(19) United States
(12) Patent Application Publication
(10) Pub. No.: US 2004/0118605 A1
(43) Pub. Date: Jun. 24, 2004

(54) Circuit board having a multi-functional hole

(76) Inventor: Ruud van der Laan, Buggenum (NL)

Correspondence Address: DUNLAP, CODDING & ROGERS P.C., PO BOX 16370, OKLAHOMA CITY, OK, 73113, US

(21) Appl. No.: 10/328,292

(22) Filed: Dec. 20, 2002

(51) Int. Cl. H05K 1/11; H05K 3/42

(52) U.S. Cl. 174/262; 174/266; 29/852

(57) ABSTRACT

A printed circuit board, comprising a substrate, a first conductor and a second conductor. The substrate having an interior surface defining a hole. The first conductor is disposed within the hole. The second conductor is disposed within the hole. The first conductor is insulated from the second conductor.

### CROSS-REFERENCE TO RELATED APPLICATIONS

Not applicable.

### STATEMENT REGARDING FEDERALLY SPONSORED RESEARCH

Not applicable.

### BACKGROUND OF THE INVENTION

Printed circuit boards are widely known in the art and are used for forming a wide variety of types of electrical devices. Printed circuit boards typically consist of a number of layers of copper conductors which are interconnected by metallized holes. The metallized holes can be in different forms, such as microvia's, buried via's, blind via's and through-holes. In each of these cases, the hole has a single function: the plating in the hole connects all copper layers exposed in the hole to each other, or the hole is used for component insertion.

The present invention, on the other hand, is directed to making one or more holes multi-functional in the interest of increasing board densities.

### SUMMARY OF THE INVENTION

The present invention relates to a printed circuit board having a substrate, a first conductor, and a second conductor. The substrate is provided with an interior surface defining a hole. The first conductor is disposed within the hole and supported by the substrate. The second conductor is disposed within the hole and is supported by the substrate. The first conductor is insulated from the second conductor. In one aspect of the invention, the substrate includes multiple layers with interleaved conducting paths and insulators.

Providing the first conductor and the second conductor, i.e., more than one insulated or isolated conductor in a single hole, has the following advantages:

1. When the hole is used for component insertion (e.g., connector), a first component can be inserted in the top portion of the hole and a second component inserted in the bottom portion of the hole with each component having separate functionality. Alternatively, the top portion can be used for component insertion while the bottom portion is used as a via.

2. When the hole is used as a via, different levels of the hole can be used for separate interconnections.

The most simple method in accordance with the present invention is to split the hole into two isolated conductors, i.e., the first conductor and the second conductor, although the present invention can be used to split a single hole into any number of conductors.

Thus, it can be seen that the present invention provides for a printed circuit board having at least two isolated conductors positioned within a hole whereby separate electrical functionality can be realized within the single hole. Other aspects of the present invention will be apparent to one skilled in the art upon review of the following detailed description in view of the attached drawings and appended claims.

### BRIEF DESCRIPTION OF THE SEVERAL VIEWS OF THE DRAWING

FIG. 1 is a cross-sectional view of a multi-layered printed circuit board constructed in accordance with the present invention.

FIGS. 2a-2d illustrate the sequential steps utilized in one method of forming the printed circuit board depicted in FIG. 1.

FIG. 3 is a second embodiment of a printed circuit board constructed in accordance with the present invention.

FIGS. 4a-4c illustrate sequential steps performed in forming the printed circuit board depicted in FIG. 3.

FIG. 5 is a cross-sectional view of a third embodiment of a printed circuit board constructed in accordance with the present invention.

FIG. 6 is a perspective view of a material removal machine having a plurality of drilling fixtures constructed in accordance with the present invention for accurately forming holes from either one or both sides of the printed circuit board.

FIG. 7 is a perspective view of a portion of the drilling fixture showing a tooling pin inserted into a soft bed.

FIGS. 8-12 show sequential steps followed when utilizing the drilling fixture for accurately drilling holes through the first side and the second side of the printed circuit board.

### DETAILED DESCRIPTION OF THE INVENTION

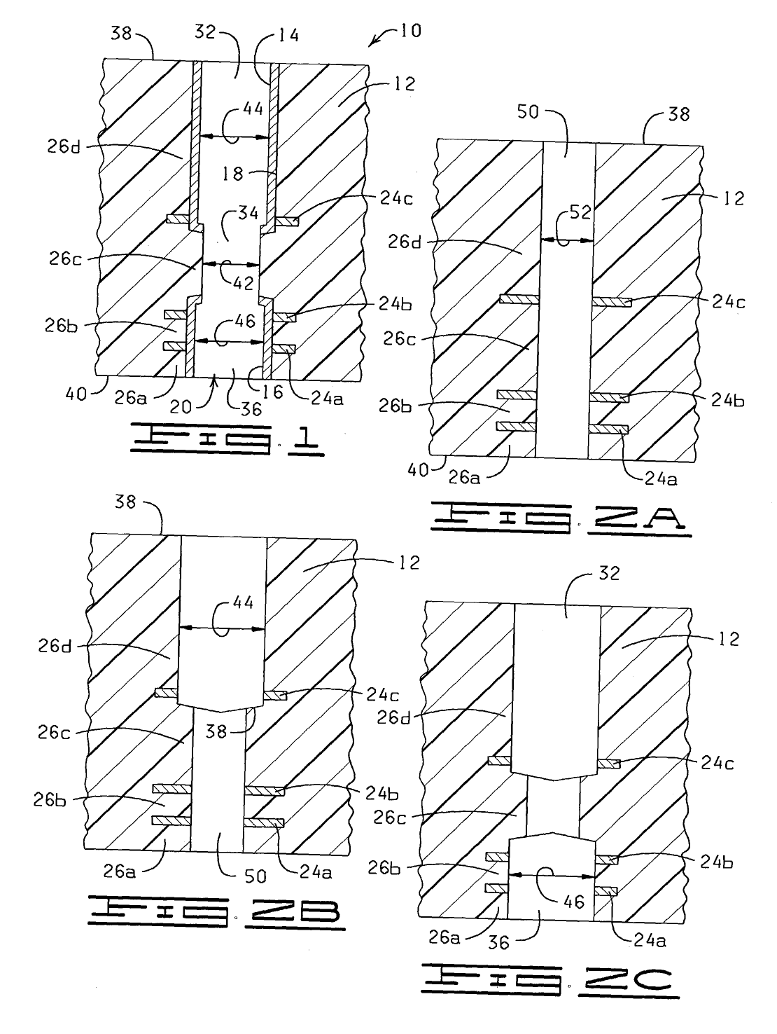

Referring now to the drawings and in particular to FIG. 1, shown therein and designated by a general reference numeral 10, is a printed circuit board constructed in accordance with the present invention. The printed circuit board 10 is provided with a substrate 12, a first conductor 14, and a second conductor 16. The substrate 12 is provided with an interior surface 18 defining a hole 20. The first conductor 14 is disposed within the hole 20 and typically supported by the substrate 12. The second conductor 16 is also disposed within the hole 20 and typically supported by the substrate 12. The first conductor 14 is isolated or insulated from the second conductor 16.

The substrate 12 can be any material capable of being utilized to support electrical components, conductors, and the like. In one preferred embodiment, the printed circuit board 10 includes multiple layers of interleaved conductive paths 24 and insulators 26. In the example shown in FIG. 1, the printed circuit board 10 includes three conductive paths 24, which are individually designated by the reference numerals 24a, 24b and 24c, and four insulators 26 which are individually designated by the reference numerals 26a, 26b, 26c and 26d. Although the printed circuit board 10, shown in FIG. 1, is provided with three conductive paths 24 and four insulators 26, it should be understood that any number of conductive paths and insulators may actually be used.

As shown in FIG. 1, the first conductor 14 contacts at least one of the conductive paths 24 (in this example, the conductive path 24c), and the second conductor 16 contacts at least another one of the conductive paths 24 (in this case, the conductive paths 24a and 24b). In this example, the second conductor 16 contacts at least two conductive paths 24a and 24b so as to provide electrical communication between the at least two conductive paths 24a and 24b.

As will be understood by one skilled in the art, the first conductor 14 and the second conductor 16 can be utilized to provide separate electrical functionality. For example, the hole 20 is provided with an upper portion 32, a medial portion 34 and a lower portion 36. The upper portion 32 of the hole 20, adjacent the first conductor 14, can be used for component insertion, and the lower portion 36 of the hole 20, adjacent the second conductor 16, can be used as a via. The lower portion 36 of the hole 20, adjacent the second conductor 16, can also be used for component insertion wherein the component is to be electrically connected to the conductive paths 24a and 24b. Although the substrate 12 has been shown in FIG. 1 as having one hole 20 formed therethrough, it should be understood that the substrate 12 can be provided with one or more holes 20 with each hole 20 having any number of upper, medial and lower portions 32, 34 or 36.

The substrate 12 has a first side 38 and a second side 40. In the example shown in FIG. 1, the upper portion 32 of the hole 20 extends into the substrate 12 a predetermined distance from the first side 38 of the substrate 12. The lower portion 36 of the hole 20 extends a predetermined distance from the second side 40 of the substrate 12. The medial portion 34 is positioned in between the upper portion 32 and the lower portion 36 of the hole 20. As shown in FIG. 1, the medial portion 34 is typically provided with a cross-sectional dimension 42 which is less than cross-sectional dimensions 44 and 46 of the respective upper portion 32 and lower portion 36 of the hole 20.

### Method of Production

As will be discussed in more detail below, the printed circuit board 10 can be basically formed utilizing the following steps:

1. Holes 20 are drilled into or through the substrate 12;

2. The interior surface 18 of the holes 20 are plated with a conductive material, such as copper or aluminum;

3. One or more specific parts of the conductive material on the interior surface 18 of the holes 20 are removed, such as by drilling, milling or laser etching, so as to isolate or insulate the conductor 14 from the conductor 16;

4. Depending on the design, plating thickness can be increased or decreased as desired.

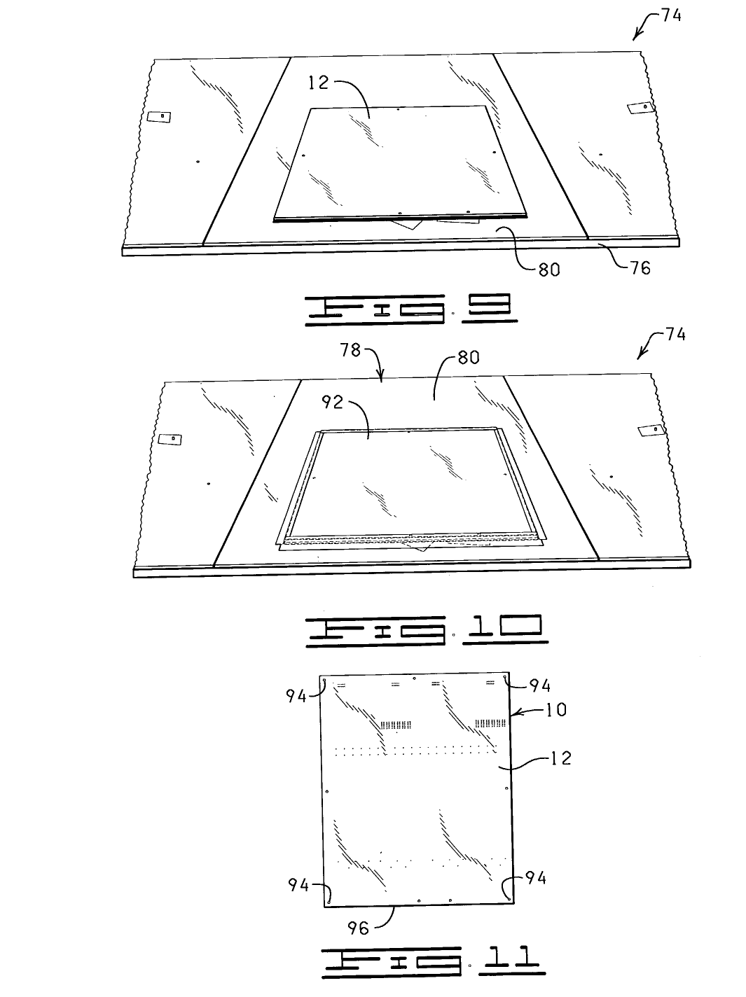

The hole 20 can be formed in the substrate 12 by a cutting process, a drilling process, a laser process, or a chemical process. In one embodiment, the hole 20 is created by a two-sided drilling process. The two-sided drilling process will be discussed in more detail with reference to FIGS. 6-13.

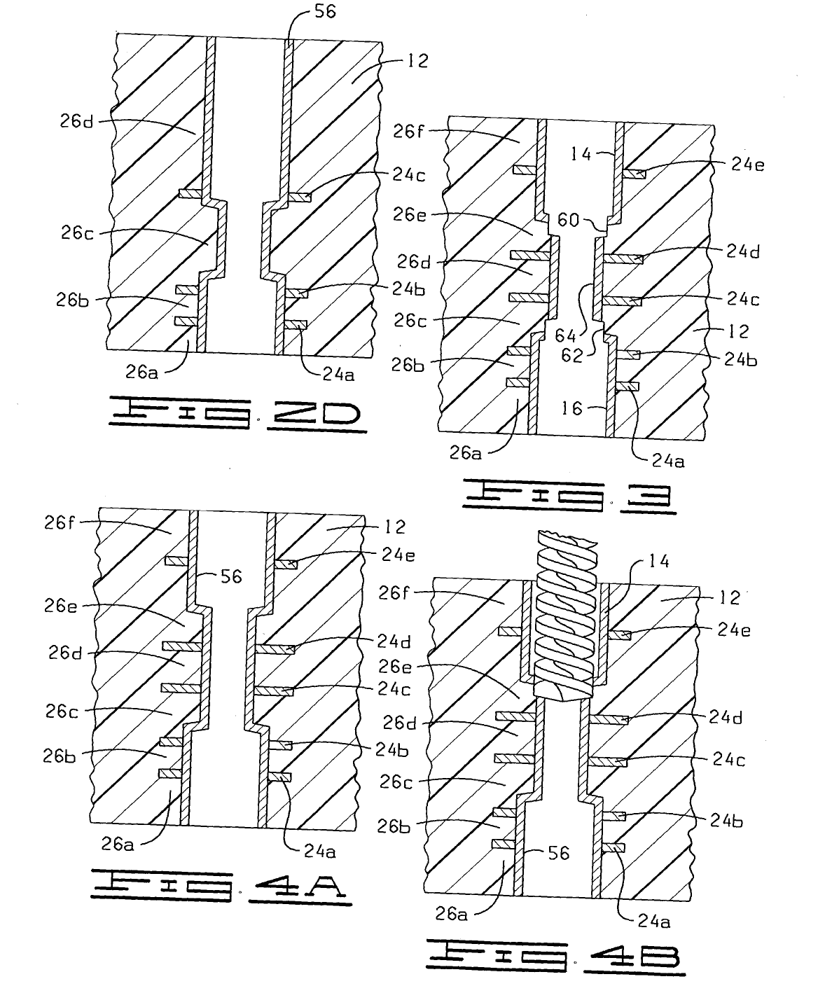

Referring now to FIG. 2a, the hole 20 is created by first drilling a pilot hole in the substrate 12. The pilot hole has a cross-sectional dimension approximately equal to the desired cross-sectional dimension of the medial portion of the hole 20.

Referring now to FIG. 2b, the upper portion 32 of the hole 20 is created by drilling from the first side 38 a predetermined distance into the substrate 12. In general, the cross-sectional dimension 52 of the medial portion 34 of the hole 20 is smaller than the cross-sectional dimension 44 of the upper portion 32 of the hole 20. Although the difference in cross-sectional dimension can vary widely, it has been found that a suitable cross-sectional dimension for the medial portion 34 of the hole 20 is about 0.10 to about 0.20 mm less than the cross-sectional dimension of the upper and lower portions 32 and 36 of the hole 20. It is envisioned that with ever increasing machine accuracies this value may be reduced significantly in the future.

The depth of the upper portion 32 of the hole 20 is dependent on the product design, for example, the depth can be the depth of the lowest interconnection to be made, or the length of a component pin to be inserted, and may be different for each hole 20 provided in the printed circuit board 10.

As shown in FIG. 2c, the lower portion 36 of the hole 20 is formed by drilling from the second side 40 of the substrate 12 a specified depth into the substrate 12. In a similar manner as discussed above, the depth of the lower portion 36 of the hole 20 will be dependent on the product design.

Referring now to FIG. 2d, a plating 56 is applied to the interior surface 18 of the hole 20 in substrate 12. Although the thickness of the plating 56 can vary depending on the product design, the plating 56 preferably has a thickness of about 10 microns. The plating 56 can be applied by any suitable process, such as electroless metal deposition, followed (depending on the application) by electrolytic metal deposition.

The thickness of 10 microns is the thickness realized by the process of elctroless copper deposition followed by electrolytic copper plating. However, it is entirely possible to only use the electroless plating, although this may be prone to damage during the second drilling step. Advancements in drilling technology will eliminate this damage, however, enabling the simpler production process. It is therefore envisioned that the thickness of the plating 56 can range between about 1 micron to about 10 microns.

Referring again to FIG. 1, the hole 20 is then drilled again to remove the plating 56 from the medial portion 34 of the hole 20 so as to isolate the first conductor 14 and the second conductor 16 from each other and thereby insulate the first conductor 14 from the second conductor 16. The plating 56 is removed from the medial portion 34 of the hole 20 with a drill [approximately 0.10 mm] smaller than the cross-sectional dimension of the upper and lower portions 32 and 36 of the hole 20. The size of the drill can vary widely and will typically be less than 0.10 mm smaller than the cross-sectional dimension of the upper and lower portions 32 and 36 of the hole 20. The difference in cross-sectional dimension, e.g., diameter, allows for drill run-out and positioning defects. The printed circuit board 10 can now be further plated and produced as a standard printed circuit board.

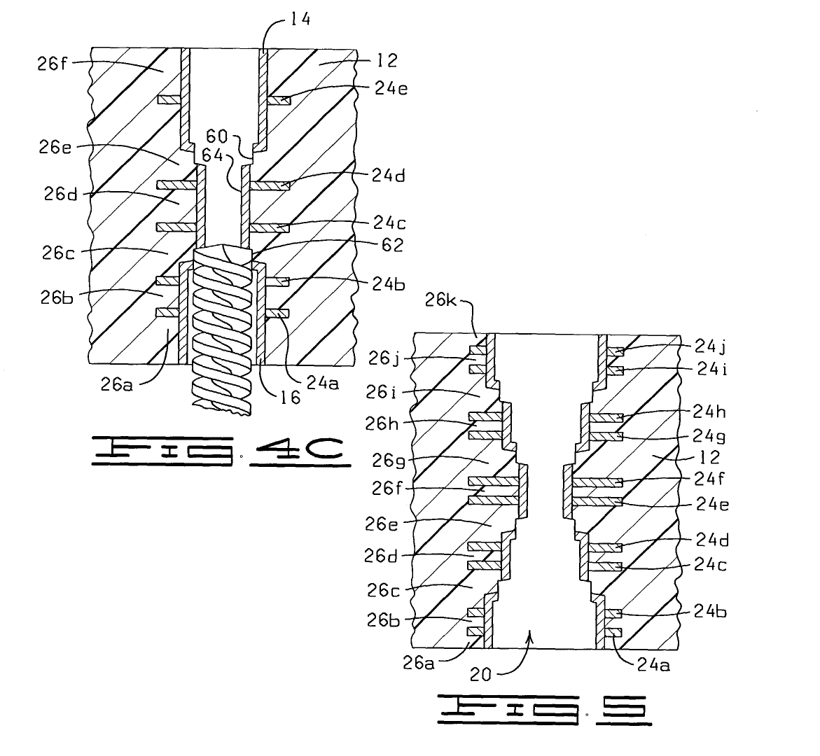

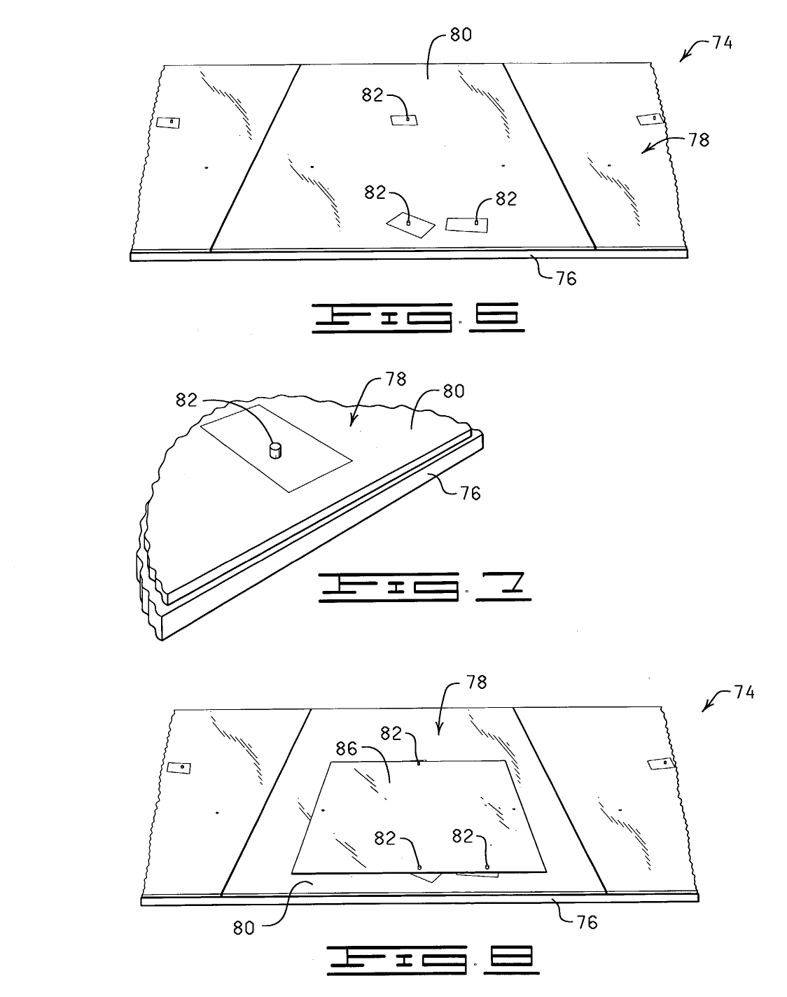

Referring now to FIGS. 3 and 4a-4c, a further development of the process in accordance with the present invention is to use depth-controlled removal of the substrate 12 and plating, such as by drilling, in a final stage, where not all of the plating 56 in the hole 20 is removed, but enough of the plating 56 is removed to cause an electrical open. That is, as shown in FIGS. 4b and 4c, a portion of the plating 56 is removed, such as by drilling, to cause an electrical break or open 60. For example, a drill can be used and inserted from the first side 38 to create the electrical open 60. In a similar manner, another portion of the plating 56 can be removed to form another electrical open 62, thereby forming three independent or insulated conductors 14, 16 and 64 as shown in FIG. 3.

The same process can be used to form the hole 20 with any number of conductors or electrical connections in the same hole as shown in FIG. 5. In FIG. 5, the hole 20 is provided with five insulated or isolated conductors.

### Two-Sided Drilling Process

As discussed, the hole 20 in the printed circuit board 10 can be formed from a process wherein the upper, medial and lower portions 32, 34 and 36 of the hole 20 are formed by drilling a pilot hole and drilling into the first side 38 and the second side 40 of the substrate 12. When drilling from the first side 38 and the second side 40 of the substrate 12, it is important that the drilling process accurately remove material from the substrate 12 so that the upper, medial and lower portions 32, 34 and 36 of the hole 20 are formed with a generally co-axial relationship.

The two-sided drilling process described herein is a method for providing accurate registration between the first side 38 and the second side 40 of the substrate 12 with currently employed equipment. However, with other machinery, for instance drilling machines equipped with a camera, x-ray camera or tactile sensors a simpler method may be used, i.e., not involving the use of soft bedding or separate board registration holes. Alternatively, less advanced applications may not need this accurate registration.

Shown in FIG. 6 is a material removal machine 74 utilized to form the hole 20. The material removal machine 74 can be an automated, computer controlled drilling or milling machine which utilizes pre-programmed settings to determine the location, depth, and size of the upper, medial and lower portions of the hole 20. For example, the material removal machine can be a model XXL5-25, obtainable from Schmoll of Germany. However, it should be understood that the material removal machine 74 is not limited to an automatic drilling machine, the material removal machine 74 can be a manual drilling or milling machine. In fact, although the process will be described hereinafter as the material removal machine 74 being a drilling machine, it should be understood that the material removal machine 74 can employ a laser, or a chemical process.

The material removal machine 74 is provided with a support member 76, and one or more drilling fixtures 78 securely attached to the support member 76. In the example shown in FIG. 6, three drilling fixtures 78 are attached to the support member 76. However, it should be understood that any number of drilling fixtures 78 can be attached to the support member 76. Further, in some instances, the material removal machine 74 can be provided with two or more separate support members 76 with any number of drilling fixtures 78 connected to the support member 76. The drilling fixtures 78 can be connected to the support member 76 by any suitable method of attachment, such as screws, adhesive, welds, or the like. Preferably, the drilling fixture 78 is removable from the support member 76, and in this instance, removable fasteners, such as screws or clamps are preferred. The support member 76 is constructed of a rigid, stable material, such as aluminum, steel, plastic, plywood or the like.

The drilling fixture 78 is includes a soft bed 80, and a plurality of tooling pins 82. A plurality of predetermined registration holes 84 are formed in the soft bed 80. The tooling pins 82 are selectively disposed into registration holes 84 in the soft bed 80 to accurately position the substrate 12 in a known location. The soft bed 80 can be formed of any device designed to offer a stable support for the tooling pins 82 and being able to be drilled into by the material removal machine 74. For example, the soft bed 80 can be constructed of plywood, fiber board, plastic, aluminum, or the like.

Referring now to FIGS. 8-12, the sequential steps followed to accurately drill holes from both sides of the substrate 12 will be described. As shown in FIG. 8, at least two of the tooling pins 82 are positioned within the soft bed 80. A backup board 86 is provided. The backup board 86 is provided with a plurality of registration holes 88 which conform to the pattern of the tooling pins 82 positioned within the tooling holes 84. The backup board 86 is positioned on the soft bed 80 such that the registration holes 88 receive the tooling pins 82. The backup board 86 is made of a material which offers support to the substrate 12 (to reduce burring) but does not greatly influence tool wear or negatively influence hole quality. The backup board 86 can be constructed of plywood, fiber board, plastic, pressed phenolic paper or the like. The backup board 86 is not strictly necessary.

The substrate 12 is also provided with a plurality of registration holes 90 (shown by way of example in FIG. 9) which correspond to the pattern of the tooling pins 82 positioned within the tooling holes 84. The substrate 12 is positioned on the backup board 86 such that the registration holes 90 are positioned on the tooling pins 82.

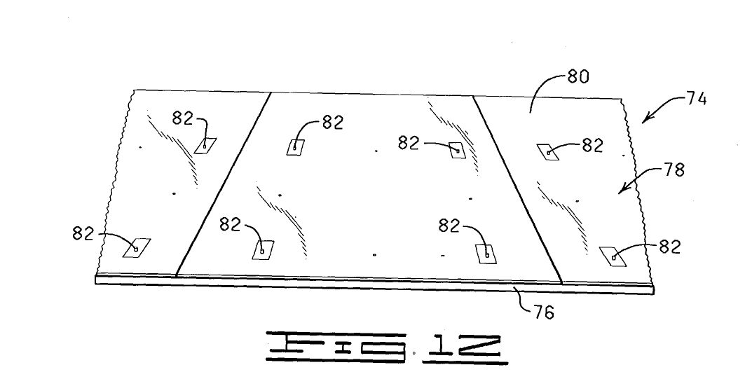

Referring now to FIG. 10, an entry material 92 is provided with registration holes 94, which also correspond to the pattern of the tooling pins 82 provided in the tooling holes 84. The entry material 92 is positioned on the substrate 12 and is taped or otherwise secured to the soft bed 80, for example, so as to secure the backup board 86, the substrate 12, and the entry material 92 to the soft bed 80. In one embodiment, the entry material 92 is not provided with the registration holes 94 in that the tooling pins 82 may not extend past the substrate 12.

While the backup board 86, substrate 12 and entry material 92 are all positioned on the tooling pins 82 and secured to the soft bed 80, the upper portion 32 and the top half of the medial portion 34 of the holes 20 are drilled through the first side 38 of the substrate 12 as discussed above with reference to FIGS. 2a-5. Depending on the application, it is possible to drill the entire medial portion 34 of the holes 20 during this step so that drilling of the smaller diameter from the second side 40 of the substrate 12 can be eliminated. In addition, a plurality of registration holes 96 are also formed through the entry material 92 and the substrate 12 while the entry material 92 and the substrate 12 are secured to the soft bed 80. The registration holes 96 are formed in a pattern corresponding to registration holes 84 formed in the soft bed 80 so that when the substrate 12 is removed from the drilling fixture 78, and turned over, the substrate 12 will be positioned in a known location so that the lower portion 32 and bottom half of the medial portion 34 of the holes 20 can be formed by drilling into the second side 40 of the substrate 12.

By way of example, and as shown in FIGS. 11 and 12, the registration holes 94 are formed in a substantially rectangular pattern about near the periphery 96 of the substrate 12. The tooling pins 82 are positioned within the tooling holes 84 corresponding to the registration holes 94. It should be understood that only two of the registration holes 94 are necessary.

While the backup board 86, substrate 12 and entry material 92 are all positioned on the tooling pins 82 and secured to the soft bed 80, lower and medial portions 32 and 34 of holes 20 are drilled through the second side 40 of the substrate 12 as discussed above with reference to FIGS. 2a-5.

While presently preferred embodiments of the present invention have been described herein, one skilled in the art will recognize that many changes or alterations can be made to the preferred embodiments without departing from the spirit and scope of the present invention. It is therefore intended that all such modifications, alterations and other changes be encompassed by the claims.

What is claimed is:

1. A printed circuit board, comprising:
a substrate having an interior surface defining a hole;
a first conductor disposed within the hole; and
a second conductor disposed within the hole, the first conductor isolated from the second conductor.

2. The printed circuit board of claim 1, wherein the substrate includes multiple layers with interleaved conductive paths and insulators.

3. The printed circuit board of claim 2, wherein the first conductor contacts at least one of the conductive paths, and the second conductor contacts at least another one of the conductive paths.

4. The printed circuit board of claim 3, wherein the first conductor contacts at least two conductive paths so as to provide electrical communication between the at least two conductive paths.

5. The printed circuit board of claim 1, wherein the first and second conductors are formed on the interior surface of the substrate with a plating process.

6. The printed circuit board of claim 1, wherein the hole is formed in the printed circuit board by a drilling process.

7. The printed circuit board of claim 1, wherein the first and second conductors provide separate electrical functionality.

8. The printed circuit board of claim 1, wherein the hole is formed by drilling from at least two sides of the printed circuit board.

9. The printed circuit board of claim 8, wherein the substrate includes at least two spatially disposed first registration holes formed therein for registering the substrate in a known location during the formation of a portion of the hole from one side of the printed circuit board.

10. The printed circuit board of claim 8, wherein the substrate is provided with a plurality of second registration holes formed therein for registering the substrate in a known location during the formation of another portion of the hole from another side of the substrate.

11. The printed circuit board of claim 10, wherein the second registration holes are formed in the printed circuit board about simultaneously with the formation of the hole in the printed circuit board.

12. A method for producing a printed circuit board, comprising the steps of:
providing at least two insulated conductors within a hole formed in a printed circuit board, the conductors being supported by the printed circuit board and disposed within the hole for providing separate electrical functionality of the conductors.

13. The method of claim 12, further comprising the step of forming a hole in the printed circuit board, the printed circuit board having a plurality of conductive paths provided in different layers of the printed circuit board.

14. The method of claim 12, wherein the step of forming the hole is defined further as drilling the hole.

15. The method of claim 12, wherein the step of providing includes the steps of:
providing a conductive material on an interior surface of the printed circuit board defining the hole; and
removing a portion of the conductive material to form the first conductor and the second conductor.

16. The method of claim 15, wherein the step of providing the conductive material is defined further as plating the conductive material on the interior surface of the printed circuit board defining the hole.
